(19) United States
(12) Patent Application Publication
(10) Pub. No.: US 2024/0249909 A1
(43) Pub. Date: Jul. 25, 2024

(54) FILLING EMPTY STRUCTURES BY DEPOSITION UNDER SEM - BALANCING PARAMETERS BY GAS FLOW CONTROL

(71) Applicant: Applied Materials Israel Ltd., Rehovot (IL)

(72) Inventors: Yehuda Zur, Tel-Aviv (IL); Konstantin Chirko, Rehovot (IL)

(73) Assignee: Applied Materials Israel Ltd., Rehovot (IL)

(21) Appl. No.: 18/099,169

(22) Filed: Jan. 19, 2023

(51) Int. Cl. H01J 37/28; H01J 37/20; H01J 37/22; H01J 37/305

(52) U.S. Cl. CPC H01J 37/28; H01J 37/20; H01J 37/222; H01J 37/3056; H01J 2237/31749

(57) ABSTRACT

A method of evaluating, with an evaluation tool that includes a first charged particle column, a region of interest on a sample that includes an array of holes separated by solid portions, the method comprising: positioning the sample such that the region of interest is under a field of view of the first charged particle column; and locally depositing material within the array of holes in the region of interest by: pulsing a flow of deposition gas to the region of interest by turning the flow of the deposition gas ON and then OFF; thereafter, scanning a charged particle beam generated by the first charged particle column across the region of interest; and iteratively repeating the pulsing and scanning steps a plurality of times to locally deposit material within the array of holes in the region of interest.

### BACKGROUND OF THE INVENTION

In the study of electronic materials and processes for fabricating such materials into an electronic structure, a specimen of the electronic structure can be used for microscopic examination for purposes of failure analysis and device validation. For instance, a specimen of an electronic structure such as a silicon wafer can be analyzed in a scanning electron microscope (SEM) or transmission electron microscope (TEM) to study a specific characteristic feature in the wafer. Such a characteristic feature may include the circuit fabricated and any defects formed during the fabrication process. An electron microscope is one of the most useful pieces of equipment for analyzing the microscopic structure of semiconductor devices.

In preparing specimens of an electronic structure for electron microscopic examination, various polishing and milling processes can be used to section the structure until a specific characteristic feature is exposed. As device dimensions are continuously reduced to the sub-half-micron level, the techniques for preparing specimens for study in an electron microscope have become more important. The conventional methods for studying structures by an optical microscope cannot be used to study features in a modern electronic structure due to the unacceptable resolution of an optical microscope.

Although TEM techniques can provide a high resolution image and a detailed description of the internal structure of a specimen that is sufficient for analysis of devices having sub-half micron features, they are only effective for electron transparent samples. Thus, it is a basic requirement for TEM samples that the sample must be thin enough to be penetrated by the electron beam and thin enough to avoid multiple scattering, which causes image blurring. The thin samples extracted from wafers for TEM processing techniques can be brittle and can be subject to fracture or crumbling. For these and other reasons, TEM imaging processes are not practical for some defect review and analysis operations.

A dual column system incorporating both a scanning electron microscope and a focused ion beam (FIB) unit can produce high resolution SEM images of a localized area of an electronic structure formed on a sample, such as a semiconductor wafer. A typical dual column system includes an SEM column, an FIB column, a supporting element that supports the sample and a vacuum chamber in which the sample is placed while being milled (by the FIB column) and while being imaged (by the SEM column).

Removing one or more selected layers (or a portion of a layer) to isolate a structure on the sample is known as delayering and can be done in a dual column system, such as that described above. For example, delayering can be done by: (i) locating a location of interest that should be milled in order to remove a certain thickness of material from the sample (the location of interest can be located by navigation of the SEM and sometimes through the use of an optical microscope), (ii) moving the sample (e.g., by a mechanical supporting element) so that the sample is located under the FIB unit, and (iii) milling the sample to remove a desired amount of material in the location of interest.

The above steps of a delayering process can be repeated many times (e.g., tens or hundreds or thousands of times) forming a hole (sometimes referred to as a box) in the specimen usually sized a few microns to few tens of microns in lateral and vertical dimensions. Additionally, the sample can be moved between the FIB and SEM columns at intervals of the delayering process to take SEM images of the surface every few nanometers of the delayering process. Tens to hundreds or more images, each representing a “slice” of the region, can then be collected at different depth intervals throughout the delayering process and used to create a three-dimensional image of the delayered region of interest.

When attempting to mill certain structures formed on a sample, the geometry of the structure being milled can present challenges for delayering the structure in a uniform manner. For example, in a device that includes an array of high aspect ratio channel holes or similar structures with solid portions (e.g., slits) between the holes, the area of the channel holes might be milled faster than the areas with solid portions making accurate metrology difficult or even impossible in those areas. Accordingly, improved milling and delayering techniques are desirable.

### BRIEF SUMMARY OF THE INVENTION

Embodiments of the disclosure pertain to an improved method and system for removing one or more selected layers (or a portion of a layer) of a sample that includes sub-half-micron features via a delayering process. Embodiments of the disclosure can be employed to uniformly delayer a portion of such a sample even if the delayered portion includes an array of high aspect ratio channel holes having solid portions formed between the holes or a similar structure. While embodiments of the disclosure can be used to delayer structures formed on a variety of different types of samples, some embodiments are particularly useful in delayering samples that are semiconductor wafers or similar specimens.

In some embodiments, a method of evaluating, with an evaluation tool that includes a first charged particle column, a region of interest on a sample that includes an array of holes separated by solid portions is provided. The method can include: positioning the sample such that the region of interest is under a field of view of the first charged particle column; and locally depositing material within the array of holes in the region of interest by: pulsing a flow of deposition gas to the region of interest by turning the flow of the deposition gas ON and then OFF; thereafter, scanning a charged particle beam generated by the first charged particle column across the region of interest; and iteratively repeating the pulsing and scanning steps a plurality of times to locally deposit material within the array of holes in the region of interest.

In some embodiments, a system for evaluating a region of a sample is provided. The system can include: a vacuum chamber; a sample support configured to hold a sample within the vacuum chamber during a sample evaluation process; a first charged particle column configured to direct a charged particle beam into the vacuum chamber toward the sample; and a processor and a memory coupled to the processor. The memory can include a plurality of computer-readable instructions that, when executed by the processor, cause the system to: position the sample such that the region of interest is under a field of view of the first charged particle column; and locally deposit material within the array of holes in the region of interest by: pulsing a flow of deposition gas to the region of interest by turning the flow of the deposition gas ON and then OFF; thereafter, scanning a charged particle beam generated by the first charged particle column across the region of interest; and iteratively repeating the pulsing and scanning steps a plurality of times to locally deposit material within the array of holes in the region of interest.

In some embodiments, a non-transitory computer-readable memory that stores a plurality of computer-readable instructions is provided. When executed by a processor operatively coupled to a system for evaluating a region of interest on a sample, the computer-readable instructions can cause a the system to: position the sample such that the region of interest is under a field of view of a first charged particle column; and locally deposit material within the array of holes in the region of interest by: pulsing a flow of deposition gas to the region of interest by turning the flow of the deposition gas ON and then OFF; thereafter, scanning a charged particle beam generated by the first charged particle column across the region of interest; and iteratively repeating the pulsing and scanning steps a plurality of times to locally deposit material within the array of holes in the region of interest.

In various implementations, the embodiments described above can include one or more of the following features. The evaluation tool can include a scanning electron microscope (SEM) column and a focused ion beam (FIB). The first charged particle column can be an SEM column. The first charged particle beam can be a high energy SEM beam generated by an SEM column. Each iteration of the pulsing and scanning steps can take less than one second. Each iteration of the introducing and scanning steps can take less than or equal to 0.1 seconds. The sample can be a semiconductor wafer. After locally depositing material within the array of holes in the region of interest, the sample can be positioned such that the region of interest is under a field of view of an FIB column and the portion of the sample that includes the plurality of holes in which the material was locally deposited can be milled by scanning a second charged particle beam generated by an FIB column across the region of interest. Milling the portion of the sample can include scanning an ion beam across both the material deposited in the array of holes and the solid portions separating the holes to iteratively delayer both the material in the array of holes and the solid portions separating the holes. After locally depositing material within the array of holes in the region of interest, a plurality of two-dimensional images of the region of interest can be acquired by alternating a sequence of delayering the region of interest with a charged particle beam from an FIB column and imaging a surface of the region of interest with an SEM column.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1A is a simplified cross-sectional view of a semiconductor wafer that includes an array of high aspect ratio channel holes separated by solid portions that can be subject to a milling operation as part of a delayering process;

FIG. 1B is a simplified cross-sectional view of the semiconductor wafer shown in FIG. 1 after a milling operation is performed on the wafer according to the prior art;

FIG. 2 is an SEM image depicting the results of an FIB milling process through an array of high aspect ratio channel holes according to the prior art;

FIG. 3 is simplified illustration of a sample evaluation systems according to some embodiments of the disclosure;

FIG. 4 is a flowchart depicting steps associated with a method of delayering a sample according to some embodiments of the disclosure;

FIGS. 5A-5C are simplified cross-sectional views of a semiconductor wafer at different stages of the delayering process set forth in FIG. 4 according to some embodiments;

FIG. 6 is a simplified cross-sectional view of a semiconductor wafer with multiple high aspect ratio holes that were only partially filled with deposition material by a high energy SEM deposition step prior to the holes being closed off by deposition in the upper portion of the holes;

FIG. 7 is a flowchart depicting steps associated with a method of delayering a sample according to some embodiments of the disclosure;

FIG. 8 is a simplified cross-sectional view of a semiconductor wafer with multiple high aspect ratio holes completely filled with deposition material by a high energy SEM deposition step in accordance with the techniques disclosed herein; and

FIG. 9 is a simplified illustration of an area on a semiconductor wafer that can be delayered according to some embodiments.

### DETAILED DESCRIPTION OF THE INVENTION

Embodiments of the disclosure can delayer a portion of a sample that includes an array of holes having solid portions formed between the holes. While embodiments of the disclosure can be used to delayer structures formed on a variety of different types of samples, some embodiments are particularly useful in delayering samples that include small feature size and/or high aspect ratio holes (e.g., holes having a diameter of 100 nm or less and/or aspect ratios of 30:1, 40:1 or 60:1 or higher) formed on semiconductor wafers or similar specimens. Non-limiting examples of small feature size, high aspect ratio holes that can be delayered according to embodiments of the disclosure include contact holes for memory channels in 3D-NAND devices and holes in which capacitors in DRAM devices can be formed.

As noted above, when standard delaying techniques are used to delayer a portion of a sample that includes an array of high aspect ratio holes with solid portions (e.g., slits) in between, the holes are typically milled faster than the slits. The inventors believe the non-uniform milling in such a sample is due to sputtering through the walls.

### Example of Standard Delayering Process

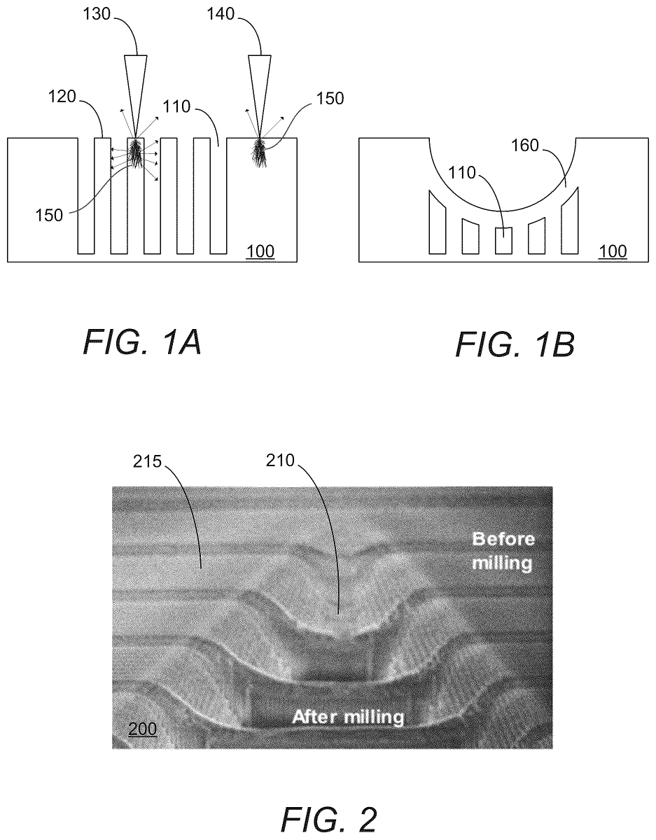

To illustrate, reference is made to FIGS. 1A and 1B, which are simplified cross-sectional views of a semiconductor wafer 100 that includes an array of high aspect ratio channel holes 110 separated by solid portions 120. In FIG. 1A, a milling operation that provides equal ion doses to all areas of the wafer (e.g., the FIB spot spends the same amount of time at each location on the wafer being milled) are performed at two separate areas. A first milling location (represented by beam 130) is performed in the array of channel holes and a second milling location (represented by beam 140) is performed in an area of semiconductor wafer 100 that does not include channel holes 110. The penetration of ions 150 in each area is representative of a real TRIM simulation.

Sputtered material from the milling operations is shown in FIG. 1A by arrows pointing away from each ion penetration area 150. The channel holes are milled faster than the slits due to sputtering through the walls. As a result, and as shown in FIG. 1B, the milling process can create a non-uniform surface with a thin layer 160 of redeposited material that is formed from material sputtered through the walls.

FIG. 2, which is an SEM image of an FIB milling process through an array of channel holes, illustrate this phenomena. Specifically, in FIG. 2 a wafer 200 is imaged at a 45 degree tilt showing a milled area 210 in the array of channel holes while an area 215 of the wafer that also includes the array of holes has not been milled. As evident from FIG. 2, milled area 210 exhibits the non-uniform, trough-shaped profile depicted in FIG. 1B that adversely impacts metrology results.

Embodiments of the disclosure overcome this challenge by filling the array of holes with a material that will avoid the above phenomena as described in detail below while still providing contrast in SEM imaging for hole metrology.

### Example Sample Evaluation System

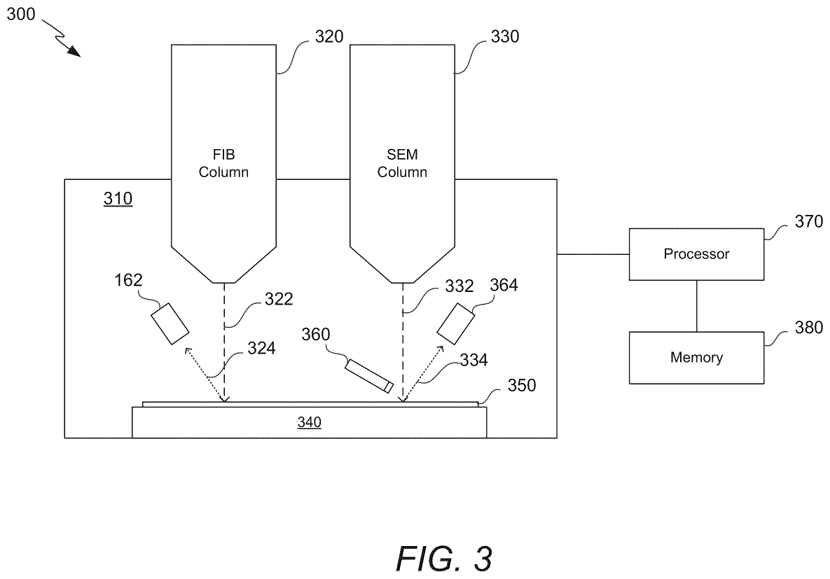

In some embodiments, the array of holes is filled by a deposition process under high-energy SEM in a dual column defect analysis system. One example of a system suitable for filling an array of holes in accordance with embodiments of the disclosure is set forth in FIG. 3, which is a simplified schematic illustration of a sample evaluation system 300 according to some embodiments of the disclosure. Sample evaluation system 300 can be used for, among other operations, defect review and analysis of structures formed on semiconductor wafers.

As shown in FIG. 3A, sample evaluation system 300 can include, among other elements, a vacuum chamber 310, a focused ion beam (FIB) column 320, a scanning electron microscope (SEM) column 330, a sample supporting element 340, a gas injection nozzle 360 and, optionally, secondary electron detectors 362, 364 (or in some embodiments, secondary ion detectors, or a combination of the two detectors working in parallel). FIB column 320 and SEM column 330 are connected to vacuum chamber 310 so that a charged particle beam generated by either one of the charged particle columns propagates through a vacuumed environment formed within vacuum chamber 310 before impinging on sample 350. For example, FIB column 320 is operable to generate a charged particle beam 322 and direct the charged particle beam 322 towards a sample 350 (sometimes referred to herein as an “object” or a “specimen”) to mill or otherwise process the sample. SEM column 330 can generate an image of a portion of sample 350 by illuminating the sample with a charged particle beam 332, detecting particles emitted due to the illumination, and generating charged particle images based on the detected particles.

The sample 350, for example a semiconductor or similar wafer, can be supported on the sample supporting element 340 within vacuum chamber 310. Sample supporting element 340 can also move regions of the sample within vacuum chamber 310 between the field of view of the two charged particle columns 320 and 330 as required for processing. For example, the FIB column 320 can be used to mill a region on the sample 350 and the supporting element 340 can then move the sample so that the SEM column 330 can image the milled region of the sample 350.

FIB column 320 can mill (e.g., drill a hole or box in) sample 350 by irradiating the sample with one or more charged particle beams to form a cross section or a hole. An FIB milling process typically operates by positioning the specimen in a vacuum chamber 310 and emitting a beam of ions 322 towards the specimen to etch or mill away material on the specimen. Common milling processes form a cross section of the sample 350 and, if desired, can also smooth the cross section. In some instances, the vacuum environment can be purged with background gases that serve to control the etch speed and other parameters. The accelerated ions can be generated from Xenon, Gallium or other appropriate elements and are typically accelerated towards the specimen by voltages in the range of 500 volts to 100,000 volts, and more, typically falling in the range of 3,000 volts to 30,000 volts. The beam current is typically in the range from several pico amps to several micro amps, depending on the FIB instrument configuration and the particular application, and the pressure is typically controlled between 10⁻¹⁰ to 10⁻⁵ mbar in different parts of the system and in different operation modes.

During a milling operation, the charged particle beam 322 generated by the FIB column 320 propagates through a vacuum environment formed within vacuum chamber 310 before impinging on the sample 350. Secondary electrons and ions 324 are generated in the collision of ions with the sample and can be detected by the detector 362. The detected secondary electrons or ions 324 can be used to analyze characteristics of the milled layers and the structure, can be used to determine an endpoint of a milling process, and/or can be used to form an images.

During a particle imaging operation, the charged particle beam 332 generated by the SEM column 330 propagates through the vacuum environment formed within the vacuum chamber 310 before impinging on the sample 350. Secondary electrons 334 are generated in the collision of electrons with the sample 350 and can be detected by the detector 364. The detected secondary electrons 334 can be used to form images of the milled area and/or to analyze characteristics of the milled layers and the structure.

Particle imaging and milling processes each typically include scanning a charged particle beam back-and-forth (e.g., in a raster scan pattern) at a constant rate across a particular area of the sample being imaged or milled. One or more lenses (not shown) coupled to the charged particle column can implement the scan pattern as is known to those of skill in the art. The area scanned is typically a very small fraction of the overall area of sample. For example, the sample can be a semiconductor wafer with a diameter of 150, 200 or 300 mm while each area scanned on the wafer can be a rectangular area having a width and/or length measured in microns or tens of microns.

One or more gases can be delivered to a sample during various operations by a gas injection system 360. For simplicity of explanation gas injection system 360 is illustrated in FIG. 3 as a nozzle, but it is noted that gas injection system 360 can include gas reservoirs, gas sources, valves, one or more inlets and one or more outlets, among other elements. In some embodiments gas injection system 360 can be configured to deliver gas to a localized area of sample 350 that is exposed to the charged particle beam as opposed to delivering gas to an entire upper surface of the sample. For example, in some embodiments gas injection system 360 has a nozzle diameter measured in hundreds of microns (e.g., between 400-500 microns) that is configured to deliver gas directly to a relatively small portion of the sample's surface that encompasses the charged particle beam scan pattern or collision zone. In various embodiments, a first gas injection system 360 can be configured to deliver gas to a sample disposed under SEM column 330 and a second gas injection system 360 (not shown) can be configured to deliver gas to a sample disposed under FIB column 320.

As shown in FIG. 3, system 300 can include one or more controllers, processors or other hardware units 370 that control the operation of system 300 by executing computer instructions stored in one or more computer-readable memories 380 as would be known to persons of ordinary skill in the art. By way of example, the computer-readable memories can include a solid-state memory (such as a random access memory (RAM) and/or a read-only memory (ROM), which can be programmable, flash-updateable and/or the like), a disk drive, an optical storage device or similar non-transitory computer-readable storage mediums.

In some embodiments SEM column 330 can be tilted relative to a surface of the sample 350 to obtain images from different angles relative to a surface of sample 350 (or from different perspectives). Alternatively, in some embodiments, the supporting element 340 can be configured to tilt the sample 350 so that images can be obtained from different angles.

The inspection system 300 shown in FIG. 3 is provided as an example of a system that can be used with some of the embodiments described herein. It should be appreciated that the embodiments are not limited to the inspection system 300, and other inspection systems can be used with some embodiments. Also, in some embodiments, an FIB tool can be used to mill a hole in a sample, and a separate SEM tool can be used to obtain images of the hole.

### Filling High Aspect Ratio Holes for Delayering Process

Some embodiments of the disclosure can fill an array of high aspect ratio holes (or similar structures) using a dual column defect analysis system, such as system 300 discussed above, by initiating a deposition process under high-energy SEM within the system. Towards this end, a deposition gas can be supplied to the sample 350 by gas supply unit 360 (or gas spraying unit 380) and energy from the SEM column 330 can generate secondary electrons. The cascade of impinging secondary electrons can, in turn, activate the deposition gas resulting in deposition of material on the sample and within the array of holes that is localized to the regions of the sample that are subject to the SEM particle beam. Thus, deposition that occurs according to such embodiments of the disclosure does not simultaneously occur across the entire surface of the sample or wafer being processed. Instead, deposition occurs only in the general areas where the SEM particle beam (which, as a non-limiting example, can have a diameter in the range of 0.5 to 10 nm) impinges upon the wafer and as the particle beam is scanned across those areas of the wafer. Thus, deposition according to some embodiments can be carried out with nanometer resolution.

The localized deposition process can fill the holes with any material that will avoid the non-uniform milling described with respect to FIGS. 1A, 1B and 2 while still providing contrast in SEM imaging for hole metrology. For example, in a high-energy SEM process (tens of kV), the penetration depth of the electrons can be over a micron. Thus, when scanning over the above geometry, the secondary electrons yield is higher through the hole walls, closer to the bottom, than at the surface. As a result, deposition according to some embodiments of the disclosure occurs more rapidly inside the holes given that the deposition gas molecules are present inside the holes. The deposited material can then fill the holes enabling the filled structures to be milled uniformly in a subsequent milling operation.

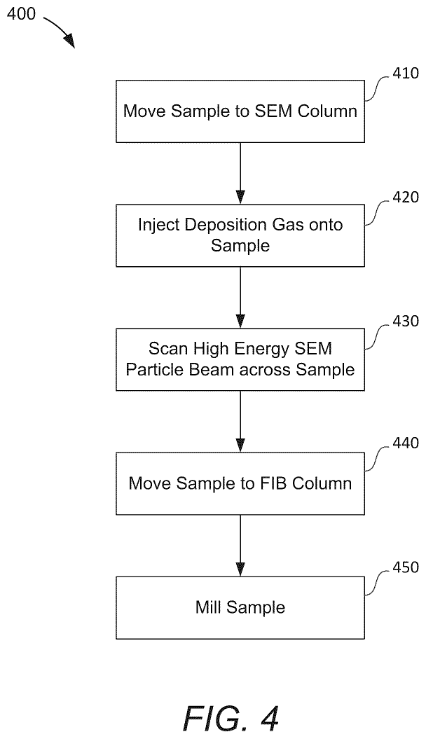

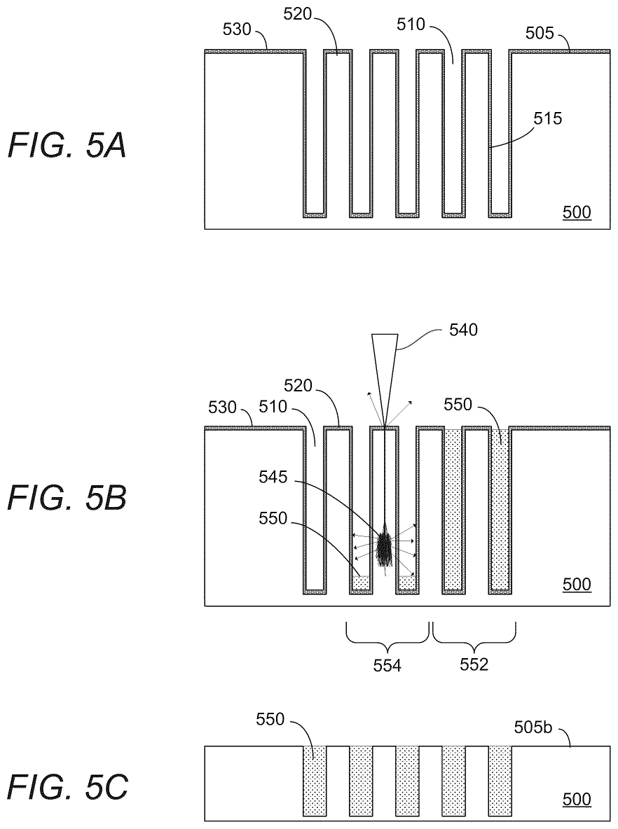

To illustrate, reference is made to FIG. 4, which is a flowchart illustrating steps associated with a method 400 according some embodiments of the disclosure, and to FIG. 5A-5C, which are a simplified cross-sectional view of a semiconductor wafer 500 subjected to the steps of method 400. Semiconductor wafer 500 can include an array of small feature size, high aspect ratio holes 510 formed therein and separated by solid portions or slits 520. Holes 510 and solid portions 520 can be similar or identical to holes 110 and slits 120 discussed above with respect to FIGS. 1A and 1B.

An initial step of method 400 can include moving the wafer 500 under the field-of-view of the SEM column (block 410). Once the wafer is properly position, a deposition gas can be injected onto the wafer (block 420). As shown in FIG. 5A, the deposition gas can adhere to the surfaces of wafer 500 including both an upper surface 505 and surfaces 515 within the holes as shown by gas layer 530. The deposition gas can be selected based on the material that holes 510 are formed in. For example, the deposition gas can be selected to deposit a material (during block 430 discussed below) that has a milling rate similar to the material that holes 510 are formed in (i.e., the material that solid portions 520 is composed of) but has a different contrast to the material of portions 520 for imaging purposes. As various examples, solid portions 520 could include carbon, silicon oxide or other appropriate materials and the deposition gas can be selected to deposit carbon, platinum, tungsten, cobalt, palladium or any appropriate material depending on the material of portions 520. In some specific examples, where the material being deposited is a metal, the deposition gas can include large molecules carrying a single atom of the metal to be deposited—for example, either tungsten hexafluoride (WF₆) or hexacarbonyltungsten (W(CO)₆) can be the deposition gas for tungsten while trimethyl(methylcyclopentadienyl) platinum ((CH₄CH₃)(CH₃)₃Pt) can be the deposition gas for platinum.

Next, method 400 can include scanning the SEM charged particle beam 540 across wafer 500 in the portions of the wafer where holes 510 that are to be subsequently milled in block 450 are formed (block 430). The charged particle beam can be focused at the surface 505 of wafer 500 to ensure a high degree of lateral accuracy and the scan rate (i.e., the beam velocity, which as would be understood by a person of skill in the art, is a combination of parameters including pixel size, dwell time and overlap) and i-probe (current) of the particle beam control the deposition rate and can be optimized for best results in terms of deposition quality within the holes. The energy level of the SEM charged particle beam 540 directed toward the wafer in block 430 can be selected such that, based on the charged particle type (e.g., electrons from the SEM column) and the penetrated material, the beam penetrates several microns below surface 505 of the wafer as shown in FIG. 5B by the penetration of electrons 545. The penetration of electrons 545 initiates a reaction in the reactive gas molecules depositing a solid material 550 within the array of holes that is localized to the area where the SEM particle beam impinges upon the wafer. That is deposition only occurs where the SEM beam impinges the wafer. The amount of deposition is controlled by the time spent scanning the injected gas with the SEM charged particle beam. Note, FIG. 5B depicts wafer 500 at a point in time after SEM beam 540 has been scanned across area 552 depositing material within the holes in area 552 and as the SEM beam 540 is just beginning to be scanned across area 554 thus initiating deposition of material within the holes in area 554.

Once SEM beam 540 has been fully scanned across the portions of the wafer that deposition is desired (e.g., across all the portions of the holes that are to be milled), material 550 will fill the holes in those areas. Next, the wafer can be moved to the field-of-view of the FIB column (block 440) and the filled areas can be milled (block 450) by the FIB column in a uniform manner as shown in FIG. 5C where, once the milling process is complete, surface 505 has been milled down to a lower relatively flat surface 505b.

### Potential Clogging at the Top of HAR Holes

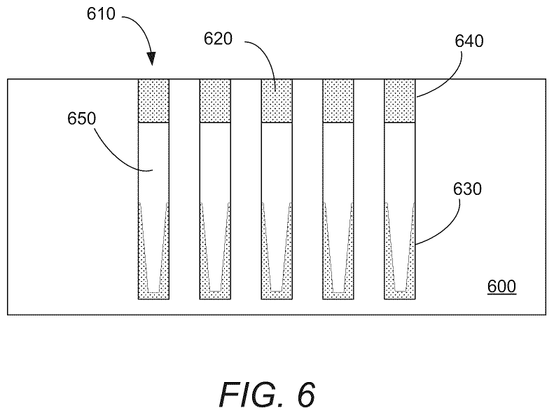

When filling high aspect ratio (HAR) holes using method 400, in some instances conditions used during the deposition steps 420, 430 can cause the holes to clog or fill at or near the top surface of the structures prior to the deposited material filling the bottom portion of the holes. An example of such is illustrated in FIG. 6, which is a simplified cross-sectional view of a semiconductor wafer 600, which includes multiple high aspect ratio holes 610 that were partially filled with deposition material 620 by a high energy SEM deposition step. As shown in FIG. 6, deposition material 620 started filling a bottom portion 630 of holes 610 but was also deposited within an upper portion 640 of the holes at a faster rate than the bottom portion. As the deposition process proceeded, the faster deposition rate in the upper portion 640 pinched off the opening to each hole 610 preventing additional gas from reaching into the hold and leaving behind an unfilled, empty gap 650 in a middle portion of each of the holes 610.

Unfiled gaps 650 can then result channel holes 610 being milled faster than the surrounding area of wafer 600 during milling step 450, which in turn can result in a non-uniform upper surface at the end of the milling process for reasons similar to those discussed above with respect to FIGS. 1A and 1B.

The clogging at the upper surface shown in FIG. 6 can occur, for example, in some instances when the deposition gas is continuously injected into the deposition region while the region is irradiated with an electron beam. While not being limited to or by any particular theory, one possible explanation for the clogging is that the top surface is more easily replenished by new molecules after irradiation from the gas phase than the lower portion of the high aspect ratio holes which relay more on diffusion due to the deep walls of the HAR structures.

### Balancing Deposition Parameters to Prevent Clogging

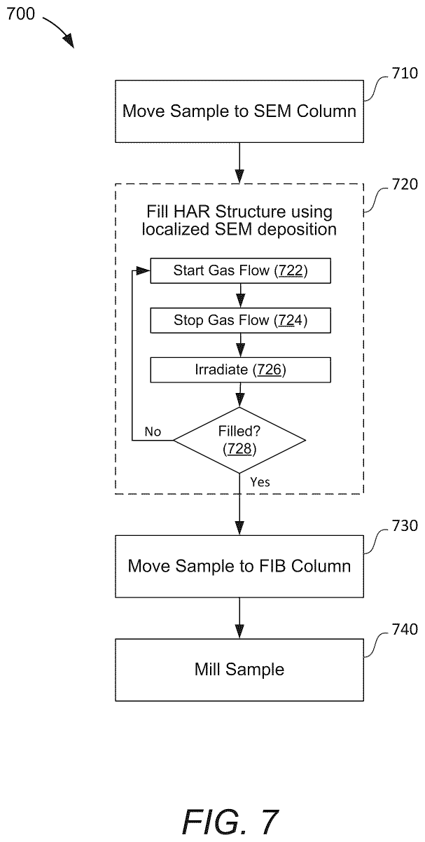

Embodiments disclosed herein can prevent such clogging by balancing the gas flow and SEM irradiation parameters. For example, to prevent the deposition from filling or clogging the upper portion of the holes before deposition fills in the bottom portion, some embodiments repeatedly alternate a flow of gas to the localized deposition area and bombarding the deposition area with a stream of electrons. To illustrate, reference is made to FIG. 7, which is a flowchart depicting steps associated with a method 700 of delayering a sample according to some embodiments.

Method 700 can start by positioning a sample (e.g., a semiconductor wafer) having a plurality of high aspect ratio holes formed thereon under the field-of-view of the SEM column (block 710). Once the wafer is properly position, the high aspect ratio holes can be filled using a localized SEM deposition process (block 720) that balances gas flow and SEM irradiation parameters in order to ensure that the upper portion of the high aspect ratio holes does not close and leave behind an unfilled, empty gap in a middle and/or lower portion of the holes as discussed above with respect to FIG. 6.

Embodiments prevent such clogging by alternating in very quick succession, at the localized deposition region, the introduction of deposition gas to the region with the bombardment of electrons in the region. For example, localized deposition step 720 can include hundreds or thousands of deposition cycles in which, during each deposition cycle, gas flux to the localized region is pulsed by quickly turning gas flow ON (block 722) and then OFF (block 724) without irradiating the region of interest. Once the gas flux is stopped, the region can then be irradiated with electrons from the SEM column (block 726) by scanning the SEM charged particle beam across the region of interest as described with respect to FIG. 4, block 430 to deposit a very thin layer material in the localized region where the SEM beam impinges the wafer. The sequency of blocks 722, 724 and 726 can then repeated (block 728) until the high aspect ratio holes are filled. In some embodiments, each of steps 722, 724 and 726 can take less than one second (and in some embodiments less than one tenth of a second) and the steps can be repeated hundreds to thousands of times before the HAR holes are filled (block 728).

In some embodiments, the irradiation of the region can be pulsed by blanking the charged particle beam (i.e., directing the charged particle beam with lenses of the SEM column so that the beam does not collide with the sample) during blocks 722 and 724 and then focusing the charged particle beam with the lenses along the scan path within the region of interest during block 726.

In each deposition cycle, when the deposition gas flow is switched ON (block 722), molecules of the deposition gas flow towards the region of interest. Gas molecules on the surface can be more quickly desorbed than molecules inside the HAR holes due to the probability of re-adsorption. Thus, when gas flow is switched OFF (block 724) and the region of interest is irradiated with electrons (block 726), there are more gas molecules in the HAR hole than at the surface the irradiation leading to more deposition within the HAR than at the surface. By constantly irradiating the sample while there are more molecules inside the holes than on the surface, material is deposited within the holes at a higher rate than at the surface.

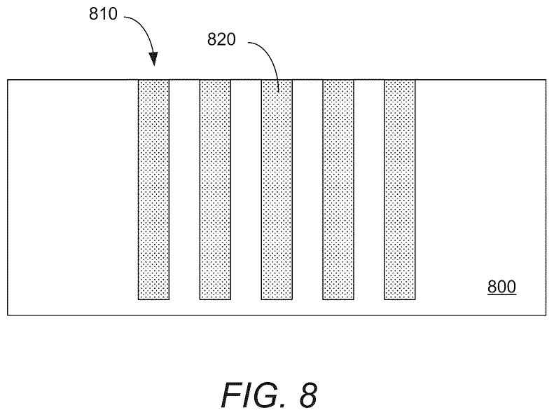

The faster deposition rate within the HAR holes can, in turn, lead to a complete filling of the holes. For example, as shown in FIG. 8, which is a simplified cross-sectional view of a semiconductor wafer 800, high aspect ratio holes 810 can be completely filled with deposition material 820 such that no holes or gaps of empty space are formed within the HAR holes 810. With some easily implemented experimentation, a person of skill in the art can readily balance the gas flux and irradiation parameters for a given deposition process and a given structure (e.g., HAR holes of a particular depth and width) to develop a process in accordance with method 700 that does not leave behind unfilled, empty gaps in the middle and/or lower portions of the holes as shown in FIG. 6 and instead completely fills the holes as shown in FIG. 8.

Once deposition process is complete and the HAR holes have been filled, the wafer can be moved to the field-of-view of the FIB column (block 730) and the filled areas can be milled (block 740) by the FIB column as described above with respect to FIG. 4, blocks 440 and 450, respectively.

### Example of a Sample to be Delayered

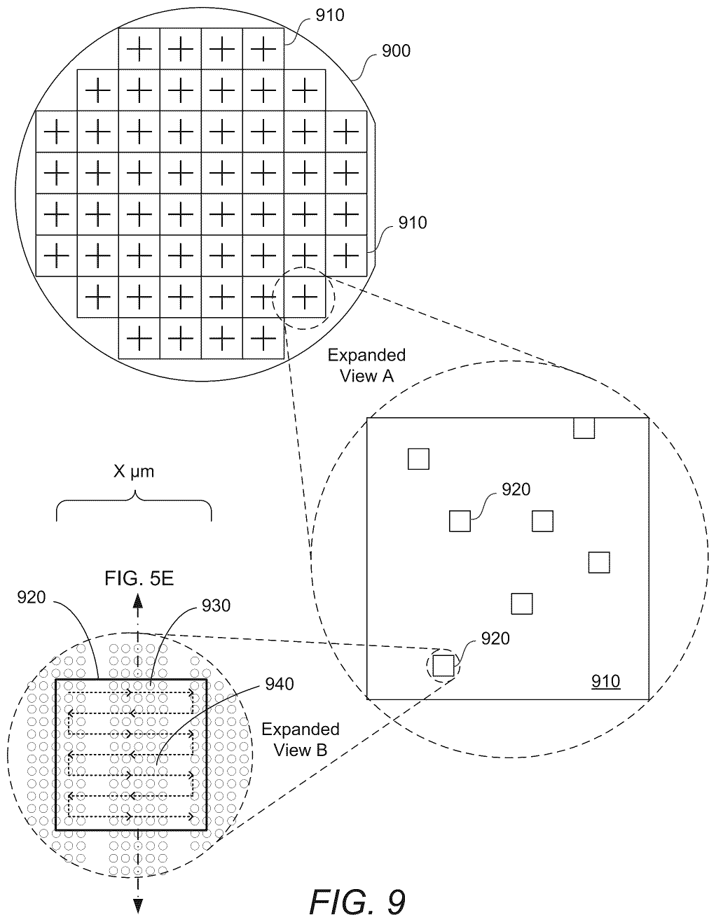

As stated above, embodiments of the disclosure can be used to fill HAR holes in a sample with deposited material prior to a delayering process in order to ensure Embodiments can be used to fill HAR holes or other structures that are on many different types of samples including electronic circuits formed on semiconductor structures, solar cells formed on a polycrystalline or other substrate, nanostructures formed on various substrates and the like. As one non-limiting example, FIG. 9 is a simplified illustration of an area on a semiconductor wafer that can be include HAR holes to be filled prior to a delayering process according to embodiments described herein. Specifically, FIG. 9 includes a top view of wafer 900 along with two expanded views of specific portions of wafer 900. Wafer 900 can be, for example, a 150 mm, 200 mm or 300 mm semiconductor wafer and can include multiple integrated circuits 910 (fifty two in the example depicted) formed thereon. The integrated circuits 910 can be at an intermediate stage of fabrication and the techniques described herein can be used to evaluate and analyze one or more regions 920 of the integrated circuits.

Embodiments of the disclosure can delayer and analyze/evaluate region 920 by sequentially milling away material within the region forming a milled hole. When milling the hole, the milling process can mill region 920 by scanning the FIB back and forth within the region according to a raster pattern until the hole has been milled to a desired depth (with the desired slope). When region 920 includes an array of high aspect ratio holes 930 separated by solid portions 940, embodiments disclosed herein can be used to deposit material filling the holes 930 prior to the delayering process in order to ensure that the delayering process is uniform without forming a trough-shaped profile or similar nonuniform milled structure as depicted in FIG. 1B that can adversely impact metrology results.

### Additional Embodiments

Any reference in the specification above to a method should be applied mutatis mutandis to a system capable of executing the method and should be applied mutatis mutandis to a computer program product that stores instructions that once executed result in the execution of the method. Similarly, any reference in the specification above to a system should be applied mutatis mutandis to a method that may be executed by the system should be applied mutatis mutandis to a computer program product that stores instructions that can be executed by the system; and any reference in the specification to a computer program product should be applied mutatis mutandis to a method that may be executed when executing instructions stored in the computer program product and should be applied mutandis to a system that is configured to executing instructions stored in the computer program product.

The foregoing description, for purposes of explanation, used specific nomenclature to provide a thorough understanding of the described embodiments. However, it will be apparent to one skilled in the art that the specific details are not required in order to practice the described embodiments. For example, while several specific embodiments of the disclosure described above use an example sample that includes an array of small feature size, high aspect ratio channel holes separated by solid slits, the disclosure is not limited to samples having such a geometry. Embodiments of the disclosure can be equally beneficially applied to delayer a sample having filled hole arrays with etched portions or slits between the filled holes. Embodiments can also be beneficially used on any sample having very small feature sizes that are etched (e.g., trenches) or otherwise formed at high aspect ratios between solid portions of the sample. Additionally, embodiments of the disclosure are not limited to delayering a sample having holes (or other features) of a particular dimensions or aspect ratio and can be beneficially applied to delayer a sample having holes or other features that are larger and/or shallower than those specifically discussed herein.

Thus, the foregoing descriptions of the specific embodiments described herein are presented for purposes of illustration and description. They are not target to be exhaustive or to limit the embodiments to the precise forms disclosed. Also, while different embodiments of the disclosure were disclosed above, the specific details of particular embodiments may be combined in any suitable manner without departing from the spirit and scope of embodiments of the disclosure. Further, it will be apparent to one of ordinary skill in the art that many modifications and variations are possible in view of the above teachings.

Because the illustrated embodiments of the present disclosure may for the most part, be implemented using electronic components and circuits known to those skilled in the art, details of such are not be explained in any greater extent than that considered necessary as illustrated above, for the understanding and appreciation of the underlying concepts of the present disclosure and in order not to obfuscate or distract from the teachings of the present disclosure.

What is claimed is:

1. A method of evaluating, with an evaluation tool that includes a first charged particle column, a region of interest on a sample that includes an array of holes separated by solid portions, the method comprising:
positioning the sample such that the region of interest is under a field of view of the first charged particle column; and
locally depositing material within the array of holes in the region of interest by:
pulsing a flow of deposition gas to the region of interest by turning the flow of the deposition gas ON and then OFF;
thereafter, scanning a charged particle beam generated by the first charged particle column across the region of interest; and
iteratively repeating the pulsing and scanning steps a plurality of times to locally deposit material within the array of holes in the region of interest.

2. The method of claim 1 wherein the evaluation tool comprises a scanning electron microscope (SEM) column and a focused ion beam (FIB) and the first charged particle column is the SEM column.

3. The method of claim 2 further comprising, after locally depositing material within the array of holes in the region of interest, positioning the sample such that the region of interest is under a field of view of the FIB column and milling the portion of the sample that includes the array of holes in which the material was locally deposited by scanning a second charged particle beam generated by the FIB column across the region of interest.

4. The method of claim 1 wherein milling the portion of the sample includes scanning an ion beam across both the material deposited in the array of holes and the solid portions separating the holes to iteratively delayer both the material in the array of holes and the solid portions separating the holes.

5. The method of claim 2 wherein each iteration of the pulsing and scanning steps takes less than one second.

6. The method of claim 2 further comprising, after locally depositing material within the array of holes in the region of interest, acquiring a plurality of two-dimensional images of the region of interest by alternating a sequence of delayering the region of interest with a charged particle beam from the FIB column and imaging a surface of the region of interest with the SEM column.

7. The method of claim 2 wherein the first charged particle beam is a high energy SEM beam generated by the SEM column.

8. The method of claim 1 wherein each iteration of the pulsing and scanning steps takes less than or equal to 0.1 seconds.

9. The method of claim 1 wherein the sample is a semiconductor wafer.

10. A system for evaluating a region of interest on a sample, the system comprising:
a vacuum chamber;
a sample support configured to hold a sample within the vacuum chamber during a sample evaluation process;
a first charged particle column configured to direct a charged particle beam into the vacuum chamber toward the sample; and
a processor and a memory coupled to the processor, the memory including a plurality of computer-readable instructions that, when executed by the processor, cause the 9 system to:
position the sample such that the region of interest is under a field of view of the first charged particle column;
locally deposit material within an array of holes in the region of interest by:
pulsing a flow of deposition gas to the region of interest by turning the flow of the deposition gas ON and then OFF;
thereafter, scanning a charged particle beam generated by the first charged particle column across the region of interest; and
iteratively repeating the pulsing and scanning steps a plurality of times to locally deposit material within the array of holes in the region of interest.

11. The system set forth in claim 10 wherein the first charged particle column is a scanning electron microscope (SEM) column and wherein the system further comprises a focused ion beam (FIB) column configured to direct a second charged particle beam into the vacuum chamber toward the sample.

12. The system set forth in claim 11 wherein the plurality of computer-readable instructions further cause the processor to, after locally depositing material within the array of holes in the region of interest, position the sample such that the region of interest is under a field of view of the FIB column and milling the region of interest that includes the array of holes in which the material was locally deposited by scanning a second charged particle beam generated by the FIB column across the region of interest.

13. The system set forth in claim 10 wherein milling the portion of the sample includes scanning an ion beam across both the material deposited in the array of holes and the solid portions separating the holes to iteratively delayer both the material in the array of holes and the solid portions separating the holes.

14. The system set forth in claim 11 wherein each iteration of the pulsing and scanning steps takes less than one second.

15. The system set forth in claim 11 wherein the plurality of computer-readable instructions further cause the processor to, after locally depositing material within the array of holes in the region of interest, acquire a plurality of two-dimensional images of the region of interest by alternating a sequence of delayering the region of interest with a charged particle beam from the FIB column and imaging a surface of the region of interest with the SEM column.

16. The system set forth in claim 11 wherein the first charged particle beam is a high energy SEM beam generated by the SEM column.

17. The system set forth in claim 10 wherein each iteration of the pulsing and scanning steps takes less than or equal to 0.1 seconds.

18. The system set forth in claim 10 wherein the sample is a semiconductor wafer.

19. A non-transitory computer-readable memory that stores a plurality of computer-readable instructions, that when executed by a processor, cause a system for evaluating a region of interest on a sample to:
Position the sample such that the region of interest is under a field of view of a first charged particle column; and
locally deposit material within an array of holes in the region of interest by:
pulsing a flow of deposition gas to the region of interest by turning the flow of the deposition gas ON and then OFF;
thereafter, scanning a charged particle beam generated by the first charged particle column across the region of interest; and
iteratively repeating the pulsing and scanning steps a plurality of times to locally deposit material within the array of holes in the region of interest.

20. The non-transitory computer-readable memory set forth in claim 19 wherein . . . wherein the plurality of computer-readable instructions further cause the processor to, after locally depositing material within the array of holes in the region of interest, position the sample such that the region of interest is under a field of view of a second charged particle column and mill the portion of the sample that includes the array of holes in which the material was locally deposited by scanning a second charged particle beam generated by the second charged particle column across the region of interest; wherein the first charged particle column is an scanning electron microscope (SEM) column and the second charged particle column is a focused ion beam (FIB) column.
